(19) United States
(12) Patent Application Publication
(10) Pub. No.: US 2019/0319142 A1
(43) Pub. Date: Oct. 17, 2019

(54) ZnO PHOTODETECTOR

(71) Applicant: Georgetown University, Washington, DC (US)

(72) Inventors: Jong-in Hahm, Washington, DC (US); Daniel S. Choi, Ellicott City, MD (US); Matthew Hansen, Waterford, VA (US); Edward Van Keuren, Washington, DC (US)

(73) Assignee: Georgetown University, Washington, DC (US)

(21) Appl. No.: 16/462,493

(22) PCT Filed: Nov. 21, 2017
(86) PCT No.: PCT/US17/62795

§ 371 Date: May 20, 2019

Related U.S. Application Data
(60) Provisional application No. 62/426,055, filed on Nov. 23, 2016.

(51) Int. Cl. H01L 31/0384; H01L 31/0224; H01L 31/0296; H01L 31/0352; H01L 31/09; H01L 31/18

(52) U.S. Cl. CPC H01L 31/03845; H01L 31/0224; H01L 31/1836; H01L 31/035227; H01L 31/09; H01L 31/0296

(57) ABSTRACT

A device comprising:
a plurality of gold nanoparticles coupled with an intertwined ZnO nanorods network, wherein the device is configured for detecting light in the visible wavelength.

This application claims the benefit of U.S. Provisional Appl. No. 62/426,055, filed on Nov. 23, 2016, and incorporated herein by reference in its entirety.

### BACKGROUND

The development of high performance visible photodetectors (PDs) is of great importance for uses ranging from biological/environmental sensors, to cameras, to military/space applications. Commercial PDs typically fabricated from Si, Ge, and GaAs are routinely used for imaging at visible and near-infrared wavelengths owing to the advantage of their fabrication compatibility with Si electronics. However, these devices can suffer from many drawbacks, including a low absorption coefficient of the active materials, photocarrier diffusion, as well as crosstalk and blurring of optical signals. Additionally, Si-based PDs usually rely on a smaller bandgap than that required for the visible detection, which can make them prone to low visible responsivity due to unwanted infrared sensitivity. Conventional GaAs PDs are often only found in space applications due to their high cost and the toxicity of the active material. Hence, there has been a strong drive to develop visible PDs by altering or replacing the light-active channels with other materials.

The utility of zinc oxide (ZnO) nanomaterials in research and development of PDs has been steadily growing and so far has been proven to be quite advantageous. In particular, PDs constructed using nanoscale ZnO as the active materials have demonstrated fast response/recovery, high on/off ratio, stability for high temperature operation, and excellent photoresponsivity in the UV region. Recent works exploiting various forms of ZnO nanomaterials as PD platforms have ranged from single ZnO NRs to ZnO thin films to ensembles of ZnO NRs. In these studies, attempts to improve photoresponsivity have been made by chemically doping ZnO with V or Co, incorporating Pt onto a ZnO thin film, changing the metal contacts to adjust the Schottky barriers, or by applying an external strain to induce a piezo-phototronic effect from a ZnO NR. Yet, the vast majority of research on ZnO-based photodetection has been largely focused on short wavelength detection in the UV region. On the contrary, very few efforts have been made to explore the use of ZnO nanomaterials for PDs functioning in the visible wavelength regime.

Performance of ZnO devices in photodetection can suffer greatly in the visible region of electromagnetic spectrum due to the nature of the photoconduction mechanism and the low light absorption efficiency. The main photoconduction mechanism from ZnO PDs in the devices described above requires incident photon energies above the band gap (E_{g}). UV illumination above the bandgap energy of 3.37 eV creates electron-hole pairs which are separated inside the ZnO channel (electrons) as well as on the ZnO surface (holes), producing photoconductivity in the device. Light in the visible region does not provide the required photon energy for devices to operate with this mechanism. In other ZnO PDs operating via a photothermally induced temperature gradient across the device channel, effective light absorption by the material is necessary. However, ZnO is transparent in the visible region, a property which is often exploited to make ‘visible-blind’ UV PDs. Consequently, illumination in the visible spectral range does not produce enough thermal gradients to generate sufficient electron carriers. For example, a ZnO PD based on this mechanism in our previous study displayed a low photovoltage (PV) of less than 3 mV in the visible region.

### SUMMARY

Disclosed herein is a device comprising:

a plurality of gold nanoparticles coupled with an intertwined ZnO nanorods network, wherein the device is configured for detecting light in the visible wavelength.

Also disclosed herein is a method for making a visible light photodetector, comprising:

depositing a plurality of gold nanoparticles onto an intertwined ZnO nanorods network via solution processing.

The foregoing will become more apparent from the following detailed description, which proceeds with reference to the accompanying figures.

### BRIEF DESCRIPTION OF THE DRAWINGS

FIG. 1 is a schematic of photodetector as disclosed herein.

FIG. 2A are SEM images displaying the typical network structures of ZnO NRs formed upon the CVD growth. The image sizes are (i) 500×500 μm², (ii) 200×200 μm², and (iii) 20×20 μm². FIG. 2B is XRD data of as-synthesized ZnO NRs in (a) scanned from 20=30-80 deg. FIG. 2C is a UV/Vis absorbance spectrum of the AuNPs used in photodetection, showing an absorption peak centered at 520 nm. The inset shows the optical image of the AuNP solution used in the experiment. FIG. 2D is a XRD spectrum of AuNPs displayed in (c) scanned from 20=30-80 deg.

FIG. 3A is an ATR FTIR spectrum of as-grown ZnO NRs (bottom) and that of AuNP-coupled ZnO NRs (top). FIG. 3B is Raman spectroscopy data of as-grown ZnO NRs (bottom) and AuNP-coupled ZnO NRs (top). The Raman intensity is normalized with respect to the Si peak appearing at 521 cm⁻¹.

FIG. 4A shows the overall schematics of the PV and PC measurement setup for our AuNP-coupled ZnO NR PDs probed under four different illumination sources. FIG. 4B is a typical PV response acquired from the ZnO NR device under 543 nm laser is charted as a function of the AuNP density loaded onto the device. FIG. 4C shows PV responsivity outputs of the AuNP-coupled ZnO NR PD in V/W are plotted as a function of increasing amount of AuNPs under the illumination wavelengths of 543 nm (red), 635 nm (purple), 785 nm (blue) and 1520 nm (black).

FIG. 4D shows the PV responsivity of the AuNP-coupled ZnO NR PD obtained at the fixed loading density of 4.8×10¹¹ AuNPs/cm² is plotted as a function of the laser wavelength. FIG. 4E shows the decreasing trend in the PV signal acquired from the AuNP-coupled ZnO NR PD is shown when the laser beam position was changed from the leftmost (1) to the middle (3) point across the device.

FIG. 4F is laser position-dependent PV data recorded from the leftmost (1) to the rightmost (5) positions are plotted for the same experimental condition of 543 nm illumination and 4.8×10¹¹ AuNPs/cm².

FIG. 5A show PC responses of the AuNP-coupled ZnO NR PD under light-on (solid) and -off (dotted) conditions are displayed for the AuNP density of 2.4×10¹¹ (red) and 4.8×10¹¹ (blue) particles/cm². FIG. 5B shows PC responsivity in A/W (left-axis) and PC in A (right-axis) are presented as a function of increasing AuNP loading density under 543 nm. FIG. 5C PC responsivity values were obtained from the AuNP-coupled ZnO NR device between a bias range of −10 to 10 V for the loading condition of 4.8×10¹¹ AuNPs/cm². The PC responsivity outputs are shown for the four different illumination cases of 543 nm (red), 635 nm (purple), 785 nm (blue) and 1520 nm (black). FIG. 5D shows the PC responsivity along with the corresponding EQE is shown for the bias sweep of 0 to 10 V at 4.8×10¹¹ AuNPs/cm².

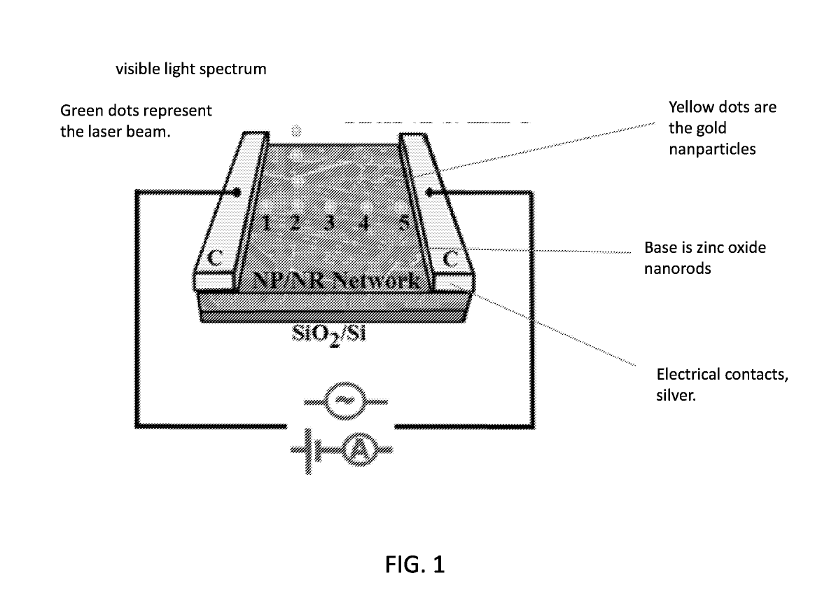

### DETAILED DESCRIPTION

Disclosed herein is a visible light photodetector operating via a photothermoelectrical mechanism. In certain embodiments, the photodetector disclosed herein does not include any electrolyte. In certain embodiments, the photodetector disclosed herein does not include any reference and/or counter electrodes. The photodetector can function, for example, as a position-dependent sensor for visible light.

In particular, disclosed herein are significantly enhanced, photoresponse behaviors of AuNP-coupled ZnO nanorod (NR) network devices in the visible wavelength range. The resulting AuNP-coupled ZnO NR devices can produce a substantial photovoltage (voltage responsivity) ˜11 mV (7.57 V/W) and a photocurrent (current responsivity) of −16 mA (0.104 A/W) at a 10 V bias under 543 nm wavelength illumination with a AuNP coverage density of 4.8×10¹¹/cm². These values are comparable to, if not far exceeding, the photoresponse capacity of most commercial PDs as well as recently reported, AuNP-coupled ZnO devices functioning at visible wavelengths. In addition, the nature and degree of the photoresponsivity enhancement are systematically elucidated by investigating their light-triggered electrical signals under varying incident wavelengths, AuNP amounts, and illumination positions. We discuss a possible photoconduction mechanism of our AuNP-coupled ZnO NR PDs and the origins of the high photoresponsivity. Specifically related to the AuNP amount-dependent photoresponse behaviors, the nanoparticle density yielding photoresponse maxima are explained as the interplay between localized surface plasmon resonance, plasmonic heating, and scattering in our photothermoelectric effect-driven device. We show that the AuNP-coupled ZnO NR PDs can be constructed via a straightforward method without the need for ultrahigh vacuum, sputtering procedures, or photo/electron-beam lithographic tools. Hence, the approach demonstrated herein may serve as a convenient and viable means to advance the current state of ZnO-based PDs for operation in the visible spectral range with greatly increased photoresponsivity. By taking advantage of the well-defined plasmon characteristics specific to the chemical make-ups, sizes, and shapes of metallic NPs, the demonstrated strategy can be further applied to effectively amplify or tune the visible photoresponsivity of other similar NR-based PDs whose photodetection capability has so far been explored largely for application in the UV region.

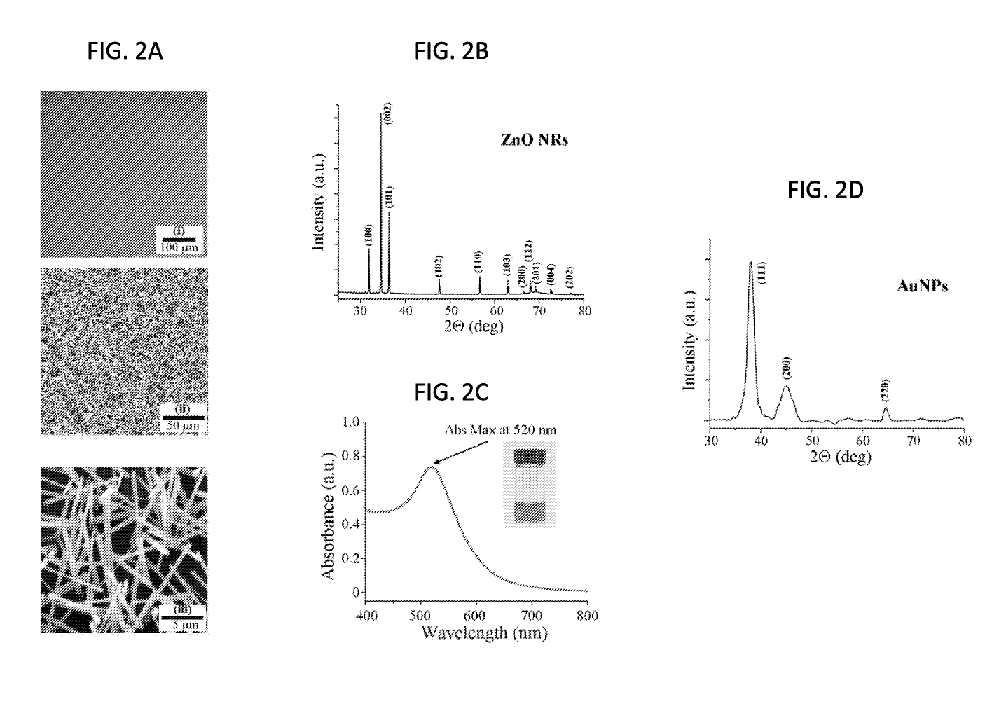

In certain embodiments, the nanorods have an aspect ratio of greater than 15:1. In certain embodiments, the nanorods have an aspect ratio of up to 100:1. In certain embodiments, the nanorods have a length greater than 5 μm. In certain embodiments, the nanorods have a length up to 40 μm. In certain embodiments, the nanorods have a diameter of 305 to 395 nm, more particularly 350 nm. As thin nanorods grow longer, they can tilt and lie toward the substrate, forming an intertwined network structure of nanorods. This ‘lying’ tendency will be greater for longer and thinner rods. The resulting structure resembles a mesh structure due to the intertwined long thin nanorods. These mesh-like images can be best seen in FIG. 2A. In certain embodiments, the structure comprises a network of nanorods that crisscross with each other. In certain embodiments, the constructs have a AuNP coverage density of 2×10¹¹ particles/cm² to 7×10¹¹ particles/cm². In certain embodiments, the AuNPs have an average diameter of 2 to 50 nm.

Various approaches have been taken to enhance the responsivity of ZnO-based devices in the visible wavelength region. A particularly promising modification scheme involves incorporating gold nanoparticles (AuNPs). Table 1 lists examples of AuNP-coupled ZnO systems in the literature, regardless of the ZnO material type and detection wavelength range used. As discussed earlier, UV is the dominant detection window even for those ZnO devices used in conjunction with AuNPs.

In addition, intricate multistep processes were often required for material preparation as well as device fabrication, including the use of high vacuum, sputtering apparatus, and photo/electron-beam lithographic tools.

TABLE 1
Various AuNP-coupled ZnO systems in the literature are summarized for their detection wavelength
range, material type/synthetic need, fabrication requirement, and photo-induced signal.

| | | Device Fabrication | | | |
|---|---|---|---|---|---|
| | | i) ZnO synthesis: sputtering/ | | | |
| | | pulsed laser deposition | PD Output | | |
| Operation | Material Type | ii) Au incorporation: sputtering | Correlated with | | |
| Wavelength | i) ZnO | iii) Contact definition: | i) AuNP amounts | | |
| range | ii) Au | photolithography/e-beam lithography | ii) Beam position | Other | Ref. |
| UV | i) single | i) No | i) No | I_{light} = 1 μA at 5 V, | [11] |
| | nanowire | ii) No | ii) No | 350 nm | |
| | ii) 30 nm | iii) Yes | | | |
| | AuNP | | | | |
| UV | i) thin film | i) Yes | i) No | I_{light} = 1.2 μA at 5 V, | [19] |
| | ii) ~20 nm | ii) | ii) No | 365 nm | |
| | thin layer | iii) Yes | | | |
| UV | i) thin film | i) Yes | i) No | predominant enhancement | [20] |
| | ii) ~10 nm | ii) Yes | ii) No | mechanism explained by | |
| | thin layer | iii) No, thermal welding | | surface states and | |
| | | | | interface states, not | |
| | | | | by surface plasmon | |
| UV | i) NR arrays | i) No | i) No | photovoltaic cell with | [21] |
| VIS | ii) 20-30 nm | ii) No | ii) not applicable | the use of a N719 dye | |
| | AuNP | iii) not applicable | | along with Au | |
| UV | i) thin film | i) Yes | i) Yes, with | photoluminescence study | [22] |
| | ii) 10-120 nm | ii) Yes | increasing Au film | under 385 nm | |
| | thin layer | iii) not applicable | thickness up to 120 | No enhancement was | |
| | | | nm | observed with Au. | |
| | | | ii) No | Enhancement with Ag. | |
| UV | i) thin film | i) No | i) No | Photocurrent | [23] |
| VIS | ii) 10-50 nm | ii) No | ii) No | responsivity = 0.35 | |
| | AuNP | iii) Yes | | mA/W at 5 V, 550 nm | |
| UV | i & ii) ~15 | i) Yes | i) No | I_{light} = 2.3 mA at 6 V | [24] |
| | nm thick co- | ii) Yes | ii) No | with 30 W Jenalux20 | |
| | sputtered | iii) Yes | | light source | |
| | Au—ZnO thin film | | | | |
| UV | i) thin film | i) No | i) No | I_{light} = 2.9 μA at 5 V, | [25] |
| | ii) 30-40 nm | ii) No | ii) No | 365 nm | |
| | AuNP | iii) Yes | | | |
| VIS | i) thin film | i) Yes | i) No | Photocurrent | [13] |
| | ii) 10-20 nm | ii) Yes | ii) No | responsivity = ~4 μA/W | |
| | AuNP | iii) Yes | | at 10 V, 550 nm | |
| VIS | i) NR mesh | i) No | i) Yes | Photocurrent | Disclosed |
| | ii) ~10 nm | ii) No | ii) Yes | responsivity = 104 mA/W | herein |
| | AuNP | iii) No | | at 10 V, 543 nm | |

Disclosed herein is a ZnO NR network-based PD interfaced with AuNP, capable of producing a significant enhancement in the PV and photocurrent (PC) outputs which are comparable to, if not far exceeding, the photoresponse capacity of most commercial PDs as well as recently reported ZnO NR-based devices functioning at visible wavelengths. We also investigate the degree of the photoresponsivity enhancement under varying incident wavelengths, AuNP amounts, and illumination positions in order to provide insight into the basis for the different degrees of photoresponsivity enhancement and the optimization of the PDs to show the largest photoresponsivity. Our overall strategy for the PD device assembly is based on a straightforward and highly scalable approach utilizing as-synthesized AuNPs and ZnO NRs. The scheme bypasses the need for complicated processing steps, highly specialized instrumentation, and lithographic tools, which can be beneficial to attaining cost effectiveness and scalability. Coupled with the well-known wavelength tunability and versatility of plasmonic nanostructures, our AuNP—ZnO NRs architecture may offer a simple and viable means to achieve low-cost, high-performing PDs with spectral tunability in the visible range.

Illustrative embodiments are described below with reference to the following numbered clauses:

1. A device comprising:

a plurality of gold nanoparticles coupled with an intertwined ZnO nanorods network, wherein the device is configured for detecting light in the visible wavelength.

2. The device of clause 1, wherein the nanorods have a diameter of 305 to 395 nm.

3. The device of clause 1 or 2, wherein the nanorods have an aspect ratio of greater than 15:1.

4. The device of any one of clauses 1 to 3, wherein the nanorods have a length greater than 5 μm.

5. The device of any one of clauses 1 to 4, wherein gold nanoparticles have an average diameter of 10 nm.

6. The device of any one of clauses 1 to 5, wherein the gold nanoparticles are applied onto the intertwined ZnO nanorods network.

7. The device of any one of clauses 1 to 5, wherein the gold nanoparticles are embedded in the intertwined ZnO nanorods network.

8. The device of any one of clauses 1 to 7, further comprising a support on which the intertwined ZnO nanorods network is disposed, and at least one electrical contact coupled to the intertwined ZnO nanorods network.

9. A method for making a visible light photodetector, comprising:

depositing a plurality of gold nanoparticles onto an intertwined ZnO nanorods network via solution processing.

Experimental

ZnO NRs were grown on a Si wafer (Silicon Quest International Inc., Santa Clara, Calif.) via chemical vapor deposition (CVD) using a similar procedure as previously described. In brief, they were generated by using a 2:1 mixture of graphite and ZnO heated to 900° C. for 1 h under a constant flow of 100 standard cubic centimeters per minute of Ar. In certain embodiments, the ZnO NRs are substantially pure n-type ZnO. As-grown ZnO nanostructures form a thin layer of densely networked NRs on the Si support. In certain embodiments, the layer of NRs is 10 to 30 μm deep. In certain embodiments, the NR network density is 10⁷ NRs/mm². In other embodiments, Al₂O₃ could be used as a support substrate for direct growth of ZnO NRs used CVD. Alternatively, the NRs can be synthesized first on a Si wafer, sonicated off from the growth substrate, dispersed in ethanol, and then deposited onto any other substrate (e.g., flexible polymers, paper).

AuNPs were synthesized from the precursor solutions of 0.4 M cetyltrimethylammonium bromide (CTAB), 0.5886 mM chloroauric acid (HAuCl₄), 1 M silver nitrate (AgNO₃), 0.1 M ascorbic acid, and 0.01 M sodium borohydride (NaBH₄). Under constant stirring at 1600 revolutions per minute (rpm), 5 mL of 0.4 M CTAB was added to 4.771 mL of DI water before introducing 17 μL of 0.5886 M HAuCl₄. Subsequent addition of 2 μL of 1 M AgNO₃ was followed by 200 μL of 0.1 M ascorbic acid. Next, 10 μL of 0.01 M NaBH₄ was added and the combined solution was stirred for 2 h at 4° C. The resulting AuNP solution was centrifuged for 20 min at 8000 rpm and the supernatant was removed. Then, the residual precipitate was reconstituted in DI water. In certain embodiments, the AuNPs are substantially pure Au with a CTAB capping layer around each AuNP.

As-grown ZnO NRs and AuNPs as well as AuNP-deposited ZnO NRs were characterized by X-ray diffraction (XRD), UV-Vis spectrometry, attenuated total reflectance (ATR) Fourier transform infrared (FTIR) spectroscopy, and Raman spectroscopy. The XRD spectra of as-synthesized ZnO NRs were acquired with a Rigaku Ultima IV X-ray diffractometer (The Woodlands, Tex.), operated with an accelerating voltage of 45 kV, under Cu Kα radiation scanned in the range of 2θ=30-80° at a rate of 2 deg/min. The AuNP solution was characterized using an Agilent 8453 UV-Vis spectrometer. FTIR data were taken using an Agilent Technologies Cary 670 Spectrometer (Santa Clara, Calif.) with a home-built ATR attachment. Raman scattering data were acquired using a Horiba LabRam HR Evolution spectrometer (Edison, N.J.) with 532 nm incident laser excitation at 25 mW power. The incident light was introduced through a 100× objective with a numerical aperture value of 0.9. Raman signals were scanned in the wavenumber range of 50-600 cm⁻¹. The size and morphology of as-synthesized ZnO NRs were examined using a FEI/Philips XL 20 scanning electron microscope (SEM) operated at 20 kV.

AuNP-coupled ZnO NR PDs were fabricated by attaching two conductive Ag (EMS, Inc. Hatfield, Pa.) contacts directly on top of the as-grown ZnO NR network layer which served as electrodes for subsequent PV and PC measurements. In other embodiments, Pt, Ni, Ru, Pd, graphite or graphene could be used for the contacts. A predetermined volume and concentration of AuNP solution was added to the surface of the ZnO NRs network device. The deposition was done in aliquots sequentially after each cycle of photoresponse measurements. Four different lasers were used as monochromatic illumination sources. They were a 543 nm HeNe laser (Newport Corp., Santa Clara, Calif.), 635 nm and 785 nm diode lasers (Thorlabs, Inc., Newton, N.J.), and a 1520 nm HeNe laser (Newport Corp., Santa Clara, Calif.) with powers of 1.46, 2.16, 2.13, and 1 mW, respectively. The incident light was sent through an optical chopper (Thorlabs, Inc., Newton, N.J.) rotating with a frequency of 515 Hz to generate light-on and -off conditions at periodic time intervals. For electrical measurements, the device was placed in a dark housing with a small front aperture to introduce the incident light source while eliminating external optical and electrical noise. At the bottom center of the enclosure, a sample holder connected the two electrodes on the sample to a Rigol DS4022 200 MHz digital oscilloscope (Beaverton, Oreg.) through a BNC connector for PV measurements. PC measurements were performed by characterizing the current-voltage (I-V) responses while sweeping the bias voltage from −10 to +10 V. The measurements were carried out using a Keithley 2634B System SourceMeter (Cleveland, Ohio) coupled with Keithley TSP® Express I-V Test software.

### Results and Discussion

FIG. 2A displays SEM images of as-grown ZnO NRs used as PDs. A mat of ZnO NRs densely covered the Si wafer surface, as evidenced in panel (i). In panel (ii) of a higher magnification, the mesh-like structures formed by interweaved NRs can be seen. The average diameter of the ZnO NRs in the network structure used in this study is 350±45 nm, as shown in panel (iii). In an effort to determine the average NR diameter accurately by clearly resolving individual NRs, the area in panel (iii) was imaged from an outermost corner of the ZnO NR mat, away from the densely grown regions of panels (i) and (ii). The XRD pattern in FIG. 2B shows the diffraction peaks characteristic of well-defined, wurtzite ZnO crystals. The respective crystallographic planes are specified next to each peak in the spectra. The sharp intense peak at 20=34.5° belongs to the preferential growth direction along the c-axis of the NR. FIG. 2C shows the UV-Vis spectrum of the as-prepared AuNP solution. The absorption maximum located at 520 nm is associated with the surface plasmon resonance (SPR) of the metallic NPs. The inset in FIG. 2C corresponds to a digital image of the AuNP solution as used for deposition onto the ZnO NR PD devices. The XRD spectrum of the AuNP is displayed in FIG. 2D, showing peaks at 20=38, 44, and 65°, characteristic of the face-centered cubic crystals. The presence of the strong peak at 20=38° relative to the broader lower peaks at 20=44° and 65° is indicative of the AuNPs containing predominantly {111} facets, as previously observed in icosahedral AuNPs complexed with CTAB.

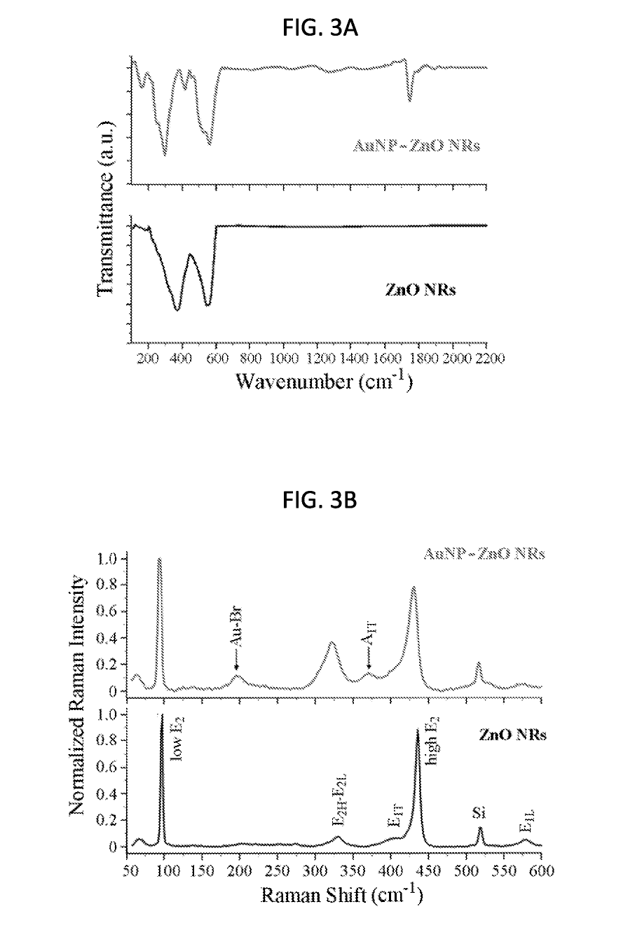

The ATR FTIR spectra of ZnO NRs and AuNP-coupled ZnO NRs (AuNP—ZnO NRs) are displayed in FIG. 3A. According to group theory, wurtzite ZnO has the optical modes of Γₒₚₜ=A₁+2B₁+E₁+2E₂ at the r point of the Brillouin zone. A₁ and E₁ are both infrared and Raman active. E₂ is Raman active whereas B₁ is a silent mode. Relatively broad but strong peaks, centered at the low-wavenumber end of the spectra in the fingerprint region of ZnO, were found in both the ATR FTIR spectra of ZnO NRs and AuNP—ZnO NRs shown in FIG. 3A. An additional peak at 1745 cm⁻¹ was observed in the ATR FTIR spectrum from AuNP—ZnO NRs as shown in the top panel of FIG. 3A. This is attributed to the tertiary amine in the AuNP-CTAB complexes. FIG. 3B displays Raman scattering data taken from ZnO NRs and AuNP—ZnO NRs. In both samples of ZnO NRs and AuNP—ZnO NRs, Raman peaks were observed at 99, 332, 437, and 581 cm⁻¹ which correspond to the Raman modes of E_{2L} (low E₂), E_{2H}-E_{2L}, E_{2H} (high E₂), and E_{1L}(low E₁), respectively. These peaks are commonly observed from the wurtzite-type ZnO structure belonging to the space group of C⁴₆ᵥ. The sharp Raman peaks of high and low E₂ reflect the chemical composition of Zn (E_{2L}) and O (E_{2H}) in the high-quality wurtzite ZnO NR sample. The E_{1L} peak, commonly associated with the presence of impurities such as O vacancies and interstitial Zn, was very weak, which corroborates the quality of the sample. With the addition of AuNPs to ZnO NRs, additional Raman peaks of 198 and 372 cm⁻¹ appeared as shown in the top panel of FIG. 3B. These resulted from the Au—Br and ZnO A_{1T} modes, respectively. The Au—Br vibrational mode at 198 cm⁻¹ is due to the AuNPs interacting with CTAB, in which bromide ion forms a bridge between the Au surface and the charged N of CTAB. The additional peak at 372 cm⁻¹ is due to the transverse Al (A_{1T}) vibrational mode of ZnO whose relatively weak Raman intensity in the blank ZnO NR sample was better resolved in the spectrum of AuNP—ZnO NRs due to the surface plasmon enhancement effect in Raman signal. A similar observation was made in a Ag—ZnO system where a coated layer of Ag on ZnO nanocrystals enhances the Raman peak associated with the A_{IT} mode of ZnO.

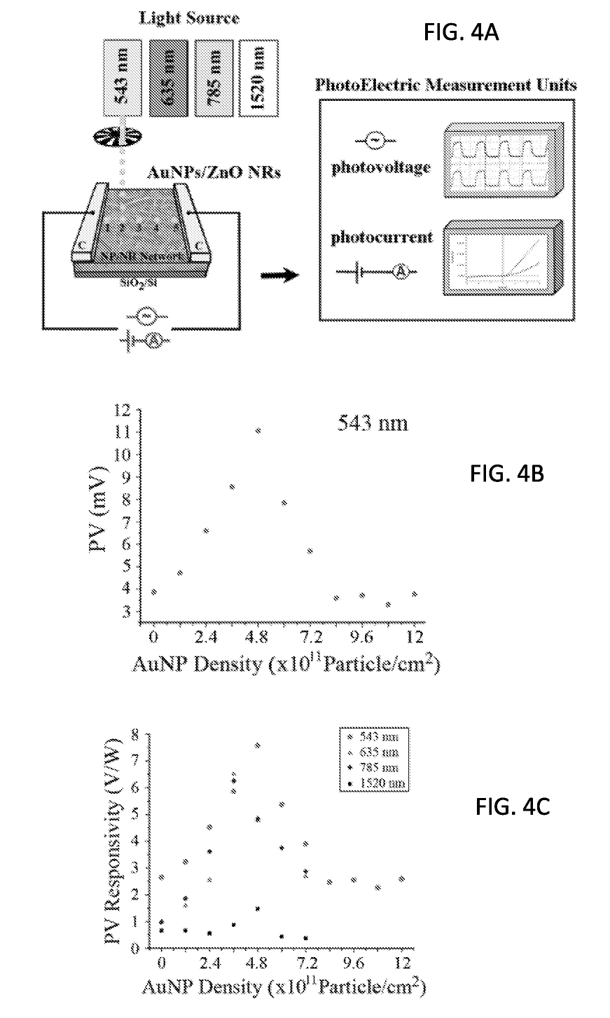

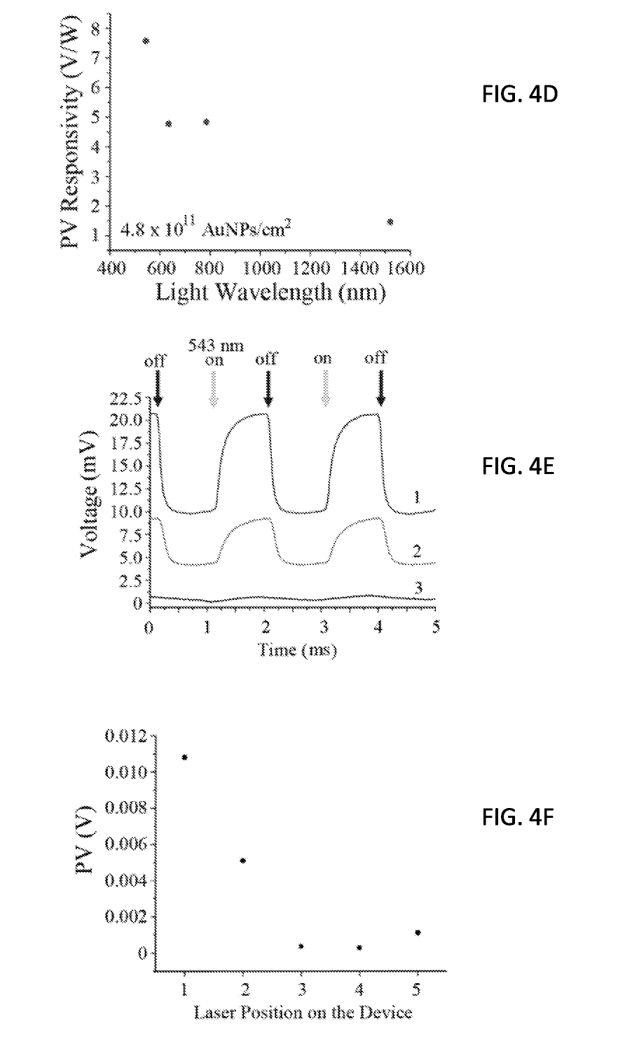

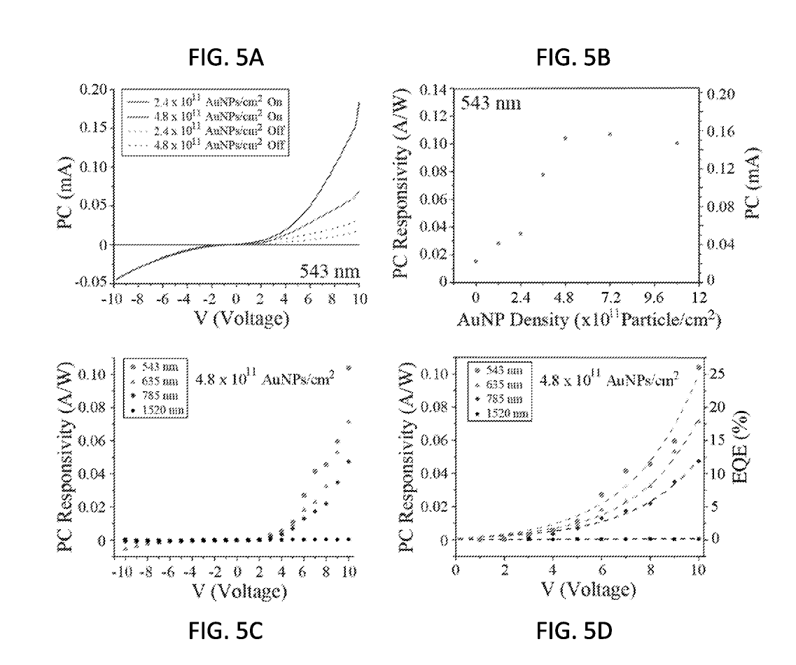

FIG. 4A illustrates the overall experimental setup used in our photoelectric measurements to record the PV and PC readings upon illumination by the four different laser wavelengths of 543, 635, 785, and 1520 nm. The schematic also shows how various points across the AuNP-coupled ZnO NR PD device were probed by moving the laser beam position. The density of AuNPs incorporated onto the ZnO NR device was controlled between 0 and 10¹¹ particles/cm², while the effect of sequentially increasing AuNP amounts on the photoresponse of the AuNP-coupled ZnO NR PD device was systematically examined. From the absorption (Abs) data shown in FIG. 2C, the size of the AuNPs was estimated as 10.6 nm using the Absₛₚᵣ/Abs₄₅₀ ratio. The concentration of the AuNP solution was determined as 5.99×10⁻⁹ M using an extinction coefficient of 1.23×10⁸M⁻¹ cm⁻¹ according to the Beer-Lambert law. The total number of the AuNPs as well as the surface density of the AuNPs used in each measurement was then calculated using the known deposition volume/area and the concentration of the AuNP solution.

FIG. 4B displays the PV values of the AuNP-coupled ZnO NR PD device obtained upon each sequential addition of AuNPs under incident 543 nm light. The simple incorporation scheme of AuNPs effectively led to approximately a three-fold increase in PV of the ZnO NR PD device. The PV signals increased gradually with more NP incorporation to the device, reaching the highest signal of ˜11 mV in PV (˜7.57 V/W in PV responsivity) when the density of AuNPs reached 4.8×10¹¹/cm². Subsequent additions of AuNPs led to a steady decrease in the PV response till it plateaued off at the signal level similar to that of the bare ZnO NR device which corresponded to ˜3.5 mV (˜2.5 V/W). The decrease in photoresponse beyond the optimal amount may be due to NP aggregation into large patches and multilayer Au accumulation on top of the device surface. Such conditions can potentially result in adverse consequences such as reducing the AuNP plasmon-aided local field enhancement and inducing more scattered light upon illumination. As the density of AuNPs in the device increases, the NPs will tend to form enlarged clusters and thicker layers, whose optical property will mimic that of an ultrathin film. However, in such a scenario where the NP coverage and effective size become larger than the wavelength of the light, the magnitude of the local electromagnetic field greatly decreases relative to that around individual AuNPs since the enhancement of the electromagnetic field known as localized surface plasmon resonance (LSPR) can no longer be achieved. In addition, the thin film-like AuNP layers can cause higher scattering of the incident light, which may prevent the incident photons from being effectively absorbed by NPs as well as the ZnO NRs underneath. From the AuNP diameter of 10.6 nm, the AuNP density at the switch-off point in the PV response is close to that at which a monolayer of the AuNPs would form on the photoactive device area.

The photoresponse measurements of the AuNP-coupled ZnO NR PD were further extended to employ other incident wavelengths. In order to rule out any potential source of errors due to device variations, the PV responses were repeatedly measured on the same device under each incident wavelength, while gradually increasing the total AuNP amounts being loaded on the ZnO NR device. FIG. 4C displays the monitored PV responsivity dependence of the PD device on the AuNP amounts for all laser lines tested. The PV responsivity (R_{PV}) was calculated by R_{PV}=Vₚₕ (P*a) where Vₚₕ, P, and a represent the measured PV, laser power, and illumination area, respectively. It followed a similar trend of the PV response as a function of the added AuNP amounts as discussed above for the case of 543 nm.

To compare the PV values between the four laser lines after accounting for the differences in the laser power and beam size, the results in FIG. 4D chart the changes in the PV responsivity of the AuNP-coupled ZnO NR PD device for all laser lines obtained at the same AuNP density of 4.8×10¹¹ particles/cm². The PV responsivity decreased from 7.57, to 4.77, to 4.84, and to 1.47 V/W when the incident laser wavelengths were changed from 543, to 635, to 785, and to 1520 nm respectively. The result indicates that the photoresponse of the device becomes highest when the wavelength of the incident light best matches the SPR absorption maximum of 520 nm for the AuNP used in the study. At the same time, the data in FIG. 4D also show that a moderate increase in the PV responsivity for the incident wavelengths of 635 and 785 nm, albeit not as high as the 543 nm case is followed by the AuNP incorporation. This observation can be attributed to the fact that the SPR absorption band of the AuNP extends over to these wavelength regions although the peak is centered at 520 nm.

Subsequently, the laser position dependence of the AuNP-coupled ZnO NR PDs was evaluated under the different illumination wavelengths. The PV responses of the AuNP-coupled ZnO NR PD were measured as a function of the laser position varying from the left (1) to the right (5) end of the device, as shown in the device schematic of FIG. 4A. The measured PV signals from the AuNP-coupled ZnO NR PD are displayed in FIGS. 4E and 4F. The PV response increased (decreased) as the laser beam was focused on the position far from (at) the center of the device. This beam position-dependency of the PV response was consistently observed regardless of the incident wavelength. For the AuNP-coupled ZnO NR PD device shown in FIGS. 4E and 4F, the highest signal was observed at position (1) with the magnitude of ˜11 mV under 543 nm illumination, whereas the lowest signal occurred when the laser was focused in the middle of the device at position (3). Although a perfect left to right symmetry in the PV response is expected in an ideal device, the measured PV signals at the two far end locations of (1) and (5) were not the same in our experiments, reflecting the inherent asymmetry associated with the AuNP-coupled ZnO NR PD devices. In our devices consisting of NR ensembles, it is likely that different contact barriers are formed at the interfaces of the left and right electrodes due to the non-uniformity of the ZnO NR network which, in turn, may result in the PV response difference measured at the two end positions. Similarly, potential variations in the NR—NR junction barriers of the NR network configuration across the device may also contribute to the asymmetry.

Similar observations have previously been made in the PV responses from PDs constructed from other single and ensemble forms of nanomaterials such as ITO NRs, MoS₂, single-walled carbon nanotubes (SWCNTs), and graphene. In these systems, the position-dependent photoresponse mechanism was explained by light-induced temperature gradients which, in turn, produce a PV through photothermoelectric effect (PTE). Upon illumination, a net electrical current can flow from the ‘hot side’ to the ‘cold side’ of the locally heated device channel until the build-up of the electric field balances this current. When the laser spot is positioned close to a contact, the PV is expected to be largest since the highest net current is expected to flow from the hot side contact close to the laser spot to the other, cold side contact. As the laser spot is moved close to the center of the device, the current caused by the temperature gradient will flow from the hot middle region equally in both directions towards the two equivalently colder contacts, resulting in a smaller net PV. Therefore, for a symmetric device, PV should be zero when the laser is positioned in the middle. Our results shown in FIG. 4F indicate an asymmetric device behavior, yielding a nonzero PV at all five laser positions tested.

Photocurrent (PC) measurements were carried out by sweeping the L-R voltage from −10 to 10 V, while keeping the laser beam maintained at the highest PV-yielding position of the device. FIG. 5A displays the representative current-voltage (I-V) curves of our AuNP-coupled ZnO NR PD devices. The I-V characteristics in FIG. 5A were recorded at the AuNP densities of 2.4×10¹¹ and 4.8×10¹¹ particles/cm² under the on (Iₚₕ) and off (I_{d}) states while using the 543 nm light. We hypothesize that our devices are governed by a barrier-dominated transport mechanism. The two electrodes in our devices form different contact barriers at the interface with the ZnO NR network due to variations in contact conditions caused by non-uniformity of the network, yielding asymmetric I-V characteristics. At the same time, NR—NR junction barriers existing in the network configuration may also contribute to the asymmetry of the I-V curves. From the PC data, PC responsivity was obtained using the formula, R_{PC}=[(Iₚₕ−I_{d})/(P*a)] where Iₚₕ and I_{d} are PC and dark current, respectively. The outcomes are plotted as a function of the AuNP amount in the PC and PC responsivity data displayed in FIG. 5B. The highest PC responsivity value of 0.104 A/W was observed at 4.8×10¹¹ AuNPs/cm² under 543 nm. Similar to the PV responsivity discussed earlier, the PC response increased by adding AuNPs up to the optimal density, beyond which the signal slowly decreased with more AuNP loading. The PC responsivity values of the same device for all four laser lines are collectively shown as a function of the bias voltage in FIG. 5C for the AuNP density of 4.8×10¹¹ particles/cm². At a bias of 10 V, PC values of 0.104, 0.0713, 0.0473, and 0.000524 A/W were obtained for the 543, 635, 785, and 1520 nm laser, respectively. As reported earlier for the PV data, the wavelength-dependency of the PC was also confirmed to be the largest with the illumination wavelength matching that of the AuNP′ SPR wavelength. FIG. 5D shows the PC responsivity and external quantum efficiency (EQE) values measured by applying a bias voltage of 0 to 10 V for all four incident wavelengths under a fixed AuNP density of 4.8×10¹¹ particles/cm². The EQE values are calculated by using the equation, EQE=R_{PC} (hc/eλ), where h, c, e, and λ are the Planck's constant, speed of light, electron charge, and incident wavelength, respectively. Under illumination with 543, 635, and 785 nm light, the PC responsivity increased exponentially as the function of the sweep voltage, while the 1520 nm light did not produce any measurable PC signal.

In our AuNP-coupled ZnO NR PD device, the maximum PC responsivity and EQE values (0.104 A/W, >25% at the bias voltage of 10 Vat 543 nm) were obtained as is without any attempts to vary contact choices or to align the NRs within the network, which makes this a highly promising system for achieving even higher sensitivity. These responsivity values are already at a level comparable to commercially available visible PDs (˜0.1-0.5 A/W at a similar bias and wavelength) and show a much improved response compared to that reported for AuNP-modified ZnO thin film structures built through elaborate fabrication procedures (˜0.004 mA/W at a 10V bias under 550 nm). In addition, the performance of our AuNP-coupled ZnO NR PD devices is highly effective (˜11 mV PV and ˜16 mA PC at a 10V bias under 543 nm with a very low laser power of 1.46 mW) relative to other visible ZnO PDs utilizing different chemical dopants and ZnO nanostructures. For instance, a Co-doped ZnO nanobelt PD was reported to produce a PV of less than 0.5 μV under 550 nm and a PC of less than 2 μA under 630 nm. An In₂O₃-sensitized ZnO nanoflower device was shown to yield a PC of ˜0.09 mA under 460 nm from a 500 W Xeon lamp at a bias of 10 V. For a ZnO nanowire-reduced graphene oxide hybrid film PD, a PV of ˜30 μV was measured upon irradiation with 532 nm light at a power of 100 W.

As for the possible origin of the PC signal increase in our AuNP-coupled ZnO NR PD devices, both plasmonically generated carriers and plasmon heating may play a role. In previous studies examining increased PC signals in the presence of metal clusters under sub-bandgap illumination, the mechanism was explained by increased generation of electron-hole pairs via the presence of surface plasmon or interband transitions in metal, injection of photoexcited carriers formed within AuNPs into the semiconductor much like a conventional metal-semiconductor PD, and injection of plasmon-triggered carriers in AuNPs to the adjacent Schottky contact layer. Among these, most of the reported literature has attributed the enhanced visible light photoresponse of metal-semiconductor PDs to plasmon-aided electron carrier generation and its injection to the semiconductor channel. This explanation is consistent with our observation of the AuNP-coupled ZnO NR photoresponse which displayed the largest sensitivity for the incident wavelength closest to the LSPR of the AuNPs. We believe that another important factor, that of plasmonic heating, may also contribute to the photoconduction seen in our devices although this has not been widely explored yet as a part of the PD mechanisms. Localized plasmonic heating from the metal NPs may significantly influence the Schottky contact barrier height and carrier mobility. The temperature change due to plasmonic heating of AuNPs can be estimated by ΔT=I₀K_{abs}r₀/4k_{inf} where his the laser power density, K_{abs} is the efficiency absorption factor for a particle of radius r₀ calculated from Mie scattering theory, k_{inf} is the coefficient of thermal conductivity of the surrounding medium at the macroscopic equilibrium temperature. Even at lower laser intensities of ˜10⁵ W/m², very sharp rises in local temperature are expected for AuNPs. This plasmonic heating mechanism is also consistent with the photoresponse of our AuNP-coupled ZnO NR PDs measured as a function of the AuNP amount. At low levels of AuNP incorporation, the photoresponse signal is anticipated to rise due to faster carrier mobility and a larger photothermal gradient enabled by locally elevated temperature. As subsequent addition of AuNPs leads to continuously increasing particle size, the photothermal efficiency is expected to decline⁵⁷ which, in turn, will yield a signal drop in PV and PC. The maximum photoresponse output will, therefore, be expected at an optimal loading level of AuNP which balances these two opposing trends arising from plasmon heating.

The incorporation of AuNPs onto the ZnO NR-based PDs led to a large increase in the PV and PC values, and this enhancement was found to be higher at an illumination wavelength closest to the SPR of the AuNPs and for laser beam positions away from the center of the active channel and nearer to a contact. In addition, the photoresponse increased with the amount of incorporated AuNPs up to a certain loading level beyond which subsequent AuNP addition led to a downward trend in photoresponse instead. A substantial PV output of ˜11 mV (PV responsivity of 7.57 V/W) was readily attained from the AuNP-coupled ZnO NR PD under 543 nm illumination. Without any attempts to vary contact choices or to align the ZnO NRs within the network, the PC responsivity of the AuNP-coupled ZnO NR PD was measured to be 0.104 A/W at a 10V bias under 543 nm. This response is comparable to or much greater than those from commercially available Si-based, and other plasmonically enhanced, ZnO-based architectures.

In view of the many possible embodiments to which the principles of the disclosed invention may be applied, it should be recognized that the illustrated embodiments are only preferred examples of the invention and should not be taken as limiting the scope of the invention.

1. A device comprising:
a plurality of gold nanoparticles coupled with an intertwined ZnO nanorods network, wherein the device is configured for detecting light in the visible wavelength.

2. The device of claim 1, wherein the nanorods have a diameter of 305 to 395 nm.

3. The device of claim 1, wherein the nanorods have an aspect ratio of greater than 15:1.

4. The device of claim 1, wherein the nanorods have a length greater than 5 μm.

5. The device of claim 1, wherein the gold nanoparticles have an average diameter of 10 nm.

6. The device of claim 1, wherein the gold nanoparticles are applied onto the intertwined ZnO nanorods network.

7. The device of claim 1, wherein the gold nanoparticles are embedded in the intertwined ZnO nanorods network.

8. The device of claim 1, further comprising a support on which the intertwined ZnO nanorods network is disposed, and at least one electrical contact coupled to the intertwined ZnO nanorods network.

9. The device of claim 8, wherein the support comprises Si.

10. The device of claim 8, wherein the contact comprises Ag.

11. The device of claim 1, wherein the ZnO is the form of wurtzite ZnO crystals.

12. The device of claim 1, wherein the gold nanoparticles have a coverage density of 2×10¹¹ nanoparticles/cm² to 7×10¹¹ nanoparticles/cm².

13. The device of claim 1, wherein the gold nanoparticles have an average diameter of 2 nm to 50 nm.

14. A device comprising:
a plurality of gold nanoparticles deposited on a ZnO nanorods network, wherein the nanorods have an aspect ratio of greater than 15:1, and the gold nanoparticles have an average diameter of 10 nm.

15. A method for making a visible light photodetector, comprising:
depositing a plurality of gold nanoparticles onto an intertwined ZnO nanorods network via solution processing.

16. The method of claim 15, further comprising growing the ZnO nanorods network on a silicon wafer via chemical vapor deposition.

17. The method of claim 16, further comprising placing at least one electrical contact onto the ZnO nanorods network.

18. The method of claim 15, wherein the ZnO nanorods have an aspect ratio of greater than 15:1.

19. A method for photodetecting light in the visible region of electromagnetic spectrum, comprising
illuminating a photodetector comprising a plurality of gold nanoparticles coupled with an intertwined ZnO nanorods network, and
measuring at least one of a resulting photovoltage or a resulting photocurrent.
